(19) United States
(12) Patent Application Publication
(10) Pub. No.: US 2026/0247917 A1
(43) Pub. Date: Aug. 20, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Shunya MIYAZAKI, Fukuoka (JP)

(73) Assignee: TOTO LTD., Fukuoka (JP)

(21) Appl. No.: 19/457,822

(22) Filed: Jan. 23, 2026

(30) Foreign Application Priority Data
Feb. 17, 2025 (JP) 2025-023140

(51) Int. Cl. H10P 72/72

(52) U.S. Cl. CPC H10P 72/722

(57) ABSTRACT

An electrostatic chuck which can reduce fluctuation in an in-plane temperature distribution of a wafer is provided. An electrostatic chuck 10 includes a dielectric substrate 100 including a surface 110 as a placement surface, an RF electrode 140 provided inside the dielectric substrate 100, a base plate 200 made of metal and joined to the dielectric substrate 100, and a conductive member 400 configured to electrically connect the RF electrode 140 and the base plate 200 to each other. A part of the conductive member 400 is accommodated in a first recessed section 160 formed in a surface 120 on the base plate 200 side of the dielectric substrate 100. An end part on the base plate 200 side of the conductive member 400 abuts against a surface 210 on the dielectric substrate 100 side of the base plate 200, or abuts against a bottom 262 of a second recessed section 260 that is formed in the surface 210 and is shallower than the first recessed section 160.

### CROSS-REFERENCE TO RELATED APPLICATION

This application is based upon and claims the benefit of priority from Japanese Patent Application No. 2025-023140 filed on Feb. 17, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

As described in International Publication No. WO 2022/255118, an RF electrode may be embedded in the dielectric substrate. The RF electrode is an internal electrode provided inside the dielectric substrate as one of a pair of counter electrodes configured to generate plasma in the semiconductor manufacturing apparatus. The RF electrode and the base plate are electrically connected to each other via a conductive member. Due to this, a potential of the RF electrode during processing of the wafer is kept at a potential of the base plate.

### SUMMARY

To electrically connect the conductive member and the RF electrode to each other, for example, a recessed section may be formed on a surface on the base plate side in the dielectric substrate, and while the RF electrode is exposed on a bottom of the recessed section, the conductive member may be accommodated in an inner side of the recessed section. Similarly, to electrically connect the conductive member and the base plate to each other, for example, a recessed section may be formed on a surface on the dielectric substrate side in the base plate, and the conductive member may be accommodated in the inner side of the recessed section. In this case, a part of the conductive member is accommodated in the recessed section of the dielectric substrate, and another part is accommodated in the recessed section of the base plate.

The base plate is required to have a function of cooling a wafer during processing via the dielectric substrate, and keeping an in-plane temperature distribution of the wafer uniform. If the above-described recessed section formed in the base plate is formed to be deep, a cooling function of the base plate in that part is lowered, and a temperature of the wafer may locally increase immediately above that portion. That is, a part of the wafer immediately above the recessed section may become a so-called “hot spot”.

The present invention has been made in view of such an issue and is aimed to provide an electrostatic chuck in which fluctuation in an in-plane temperature distribution of a wafer can be reduced.

To address the above-mentioned issue, an electrostatic chuck according to the present invention includes a dielectric substrate including a placement surface on which an object to be attracted is placed, an internal electrode provided inside the dielectric substrate, a base plate made of a metal and joined to the dielectric substrate, and a conductive member configured to electrically connect the internal electrode and the base plate to each other. A part of the conductive member is accommodated in a first recessed section formed in a surface on the base plate side of the dielectric substrate. An end part on the base plate side of the conductive member abuts against a surface on the dielectric substrate side of the base plate, or abuts against a bottom of a second recessed section that is formed in the surface and is shallower than the first recessed section.

In the electrostatic chuck having such a configuration, at a position of the base plate corresponding to the conductive member, the second recessed section that may cause a hot spot is formed to be relatively shallow, or the second recessed section itself is not formed. Due to this, a local temperature increase immediately above the conductive member is suppressed, so that fluctuation in an in-plane temperature distribution of the wafer during processing can be reduced.

According to the present invention, it is possible to provide an electrostatic chuck which can reduce fluctuation in an in-plane temperature distribution of a wafer.

### BRIEF DESCRIPTION OF THE DRAWINGS

FIG. 1 is a cross sectional view schematically illustrating a configuration of an electrostatic chuck according to a first embodiment;

FIG. 2 is a cross sectional view illustrating a detail of a configuration of a conductive member and its neighboring part of the electrostatic chuck according to the first embodiment;

FIG. 3 is a perspective view illustrating the configuration of the conductive member;

FIG. 4 is a diagram for explaining a method of manufacturing the electrostatic chuck according to the first embodiment;

FIG. 5 is a cross sectional view illustrating a detail of a configuration of a conductive member and its neighboring part of an electrostatic chuck according to a second embodiment; and

FIG. 6 is a cross sectional view illustrating a detail of a configuration of a conductive member and its neighboring part of an electrostatic chuck according to a third embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

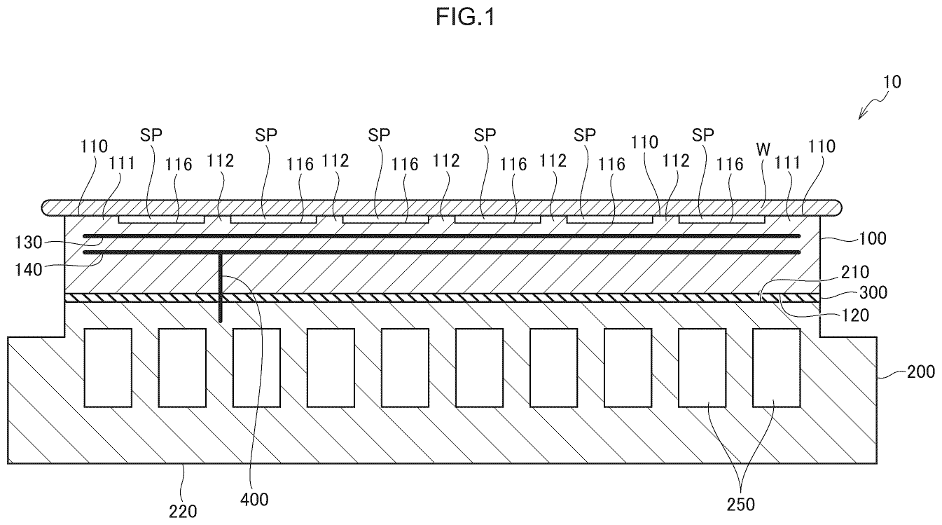

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various publicly known configurations can be adopted. The single attraction electrode 130 may be provided as so-called a “monopolar” electrode as in the present embodiment, but may also include two attraction electrodes as so-called “bipolar” electrodes.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and is used for processing such as film deposition and etching on the wafer W. The RF electrode 140 corresponds to an “internal electrode” in the present embodiment.

Similarly to the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position closer to the surface 120 side than the attraction electrode 130. Similarly to the attraction electrode 130, the RF electrode 140 is arranged so as to be parallel to the surface 110. The RF electrode 140 is a single electrode which is substantially circular in top view. In top view, a center of the RF electrode 140 matches a center of the dielectric substrate 100.

A conductive member 400 is provided in the electrostatic chuck 10. The conductive member 400 is a member configured to electrically connect the RF electrode 140 and the base plate 200 which will be described below to each other. By the conductive member 400, a potential of the RF electrode 140 during the process on the wafer W becomes the same as a potential of the base plate 200. In FIG. 1, the conductive member 400 is schematically depicted as a simple straight line. A specific shape of the conductive member 400 will be described later.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 serves as a part of the surface 110 and abuts against the wafer W. The distal end of the seal ring 111 can be referred to as a part on an outermost circumferential side on the surface 110 which serves as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase dielectric withstand voltage of the base plate 200. The insulating film may be formed so as to cover the entire surface of the base plate 200, or may be formed so as to cover only a part of the surface of the base plate 200, for example, only the surface 210.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

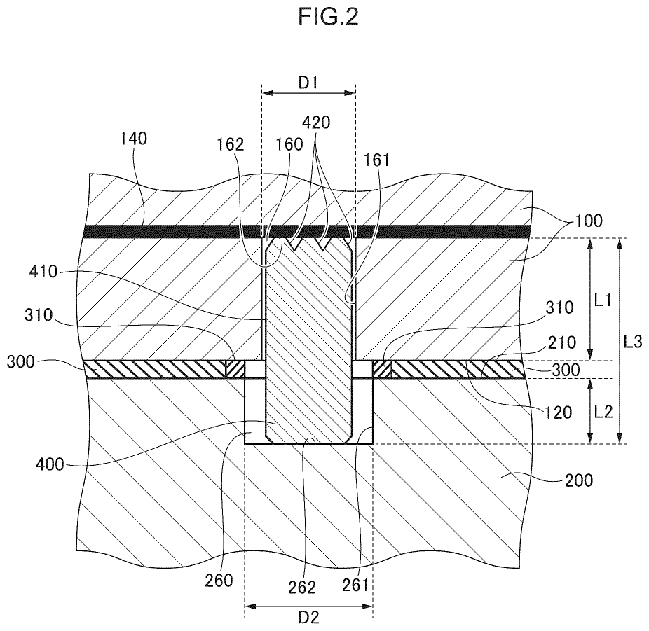

A specific configuration of the conductive member 400 and its neighboring part will be described with reference to FIG. 2. As illustrated in FIG. 2, a first recessed section 160 is formed in the surface 120 on the base plate 200 side of the dielectric substrate 100. The first recessed section 160 is a part obtained by causing a part of the surface 120 to retreat towards the surface 110 in a recessed shape to enable the conductive member 400 to be arranged. The first recessed section 160 of the present embodiment is formed up to a depth position in which the RF electrode 140 is to be exposed. For this reason, the RF electrode 140 serving as the internal electrode is exposed in a bottom 162 of the first recessed section 160. A shape of the first recessed section 160 in top view is circular, and a space of a substantially cylindrical shape is formed in an inner side of the first recessed section 160.

A second recessed section 260 is formed in the surface 210 on the dielectric substrate 100 side of the base plate 200. The second recessed section 260 is formed in a portion overlapped with the first recessed section 160 in the surface 210 in top view. The second recessed section 260 is a part obtained by causing a part of the surface 210 to retreat towards the surface 220 in a recessed shape to enable the conductive member 400 to be arranged. A metallic part of the base plate 200 is exposed in whole in an inner side of the second recessed section 260. A shape of the second recessed section 260 in top view is circular, and a space of a substantially cylindrical shape is formed in the inner side of the second recessed section 260. A central axis of the second recessed section 260 matches a central axis of the first recessed section 160. It is however noted that a diameter D2 of an inner circumferential surface 261 of the second recessed section 260 is larger than a diameter D1 of an inner circumferential surface 161 of the first recessed section 160.

A circular opening is formed in a part between the first recessed section 160 and the second recessed section 260 in the joining layer 300. The first recessed section 160 and the second recessed section 260 are connected to each other via the opening, and a whole of these becomes one space.

A member denoted by reference sign “310” in FIG. 2 is a member arranged so as to avoid intrusion of an uncured adhesive into the inner sides of the first recessed section 160 and the second recessed section 260. The member will also be hereinafter referred to as a “blocking section 310”. The blocking section 310 is an annular member arranged so as to surround the second recessed section 260 over the whole circumference from the outer side in top view. An inner diameter of the blocking section 310 is the same as an inner diameter of the second recessed section 260 (the diameter D2 described above), but may have a size different from the inner diameter of the second recessed section 260. As the blocking section 310, for example, a cured silicone adhesive is used.

The conductive member 400 is a member of a substantially cylindrical shape which is formed of a fibrous metal member, and is accommodated in the inner sides of the first recessed section 160 and the second recessed section 260. That is, a part of the conductive member 400 is accommodated in the first recessed section 160, and another part of the conductive member 400 is accommodated in the second recessed section 260. In top view, a diameter of the part accommodated in the first recessed section 160 in the conductive member 400 is equal to a diameter of the part accommodated in the second recessed section 260 in the conductive member 400.

An end part on the dielectric substrate 100 side of the conductive member 400 (an end part on the upper side in FIG. 2) abuts against the RF electrode 140 that is exposed at the bottom 162 of the first recessed section 160. An end part on the base plate 200 side of the conductive member 400 (an end part on the lower side in FIG. 2) abuts against a bottom 262 of the second recessed section 260. The RF electrode 140 and the metallic part of the base plate 200 are electrically connected to each other by the thus arranged conductive member 400.

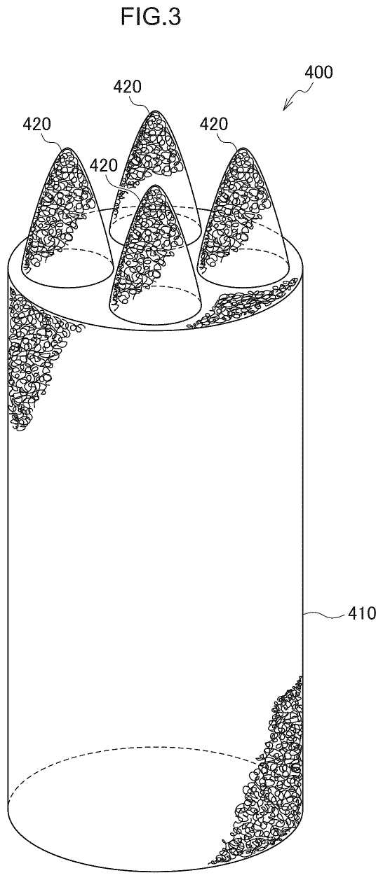

As illustrated in FIG. 3, the conductive member 400 includes a main body section 410 of a substantially cylindrical shape and a plurality of protrusion sections 420, and an entirety thereof is integrally formed of the fibrous metal member. The protrusion section 420 is a protrusion of a substantially cylindrical shape which is formed so as to extend from the surface on the dielectric substrate 100 side in the main body section 410 further towards the dielectric substrate 100. In the present embodiment, four in total of the protrusion sections 420 are formed, but the number of the protrusion sections 420 may be different from four.

The conductive member 400 formed of the fibrous metal member has a breathability to such an extent that allows air or a fluid such as an adhesive to intrude into the inside of the conductive member 400. That is, the fibrous metal member is not sufficiently dense, and there is a gap between mutual fibers. When such a configuration is adopted, the conductive member 400 serves as an elastic body in which each section including the protrusion section 420 may be easily deformed by an external force.

A dimension in an up and down direction (direction in which the protrusion section 420 extends) of the conductive member 400 when the external force is not received is larger than a dimension in the same direction in the state of FIG. 2. That is, in a state in which the conductive member 400 is compressed along the direction from the dielectric substrate 100 towards the base plate 200, the conductive member 400 is accommodated in the inner sides of the first recessed section 160 and the second recessed section 260 and sandwiched between the RF electrode 140 and the base plate 200. A distal end of each of the protrusion sections 420 is elastically deformed so as to collapse by being pressed against the bottom 162 of the first recessed section 160 (that is, the RF electrode 140).

The conductive member 400 is in a state of being pressed against each of the RF electrode 140 and the base plate 200 by its own restoring force. For this reason, during the process on the wafer W or the like, even when a thermal expansion or contraction occurs in each section of the electrostatic chuck 10, the electrical connection between the RF electrode 140 and the base plate 200 is regularly maintained.

The number of the conductive members 400 may be one or more. For example, an aspect may be adopted in which a plurality of spaces composed of the first recessed section 160 and the second recessed section 260 are formed to be aligned along a circumferential direction, and the conductive members 400 are accommodated one by one in each of the spaces.

A shape different from that of the present embodiment may be adopted as the shape of the conductive member 400. For example, the entirety of the conductive member 400 may have a substantially cylindrical shape and a shape without including the protrusion section 420.

Returning to FIG. 2, the description will be continued. In FIG. 2, “L1” represents a depth of the first recessed section 160. The depth in the present embodiment is equal to a distance from the surface 120 to the bottom 162. It can also be said that L1 is a dimension, along a direction perpendicular to the placement surface, of a part of the conductive member 400 that is accommodated in the first recessed section 160 in the state of FIG. 2.

In FIG. 2, “L2” represents a depth of the second recessed section 260. The depth in the present embodiment is equal to a distance from the surface 220 to the bottom 262. It can also be said that L2 is a dimension, along the direction perpendicular to the placement surface, of a part of the conductive member 400 that is accommodated in the second recessed section 260 in the state of FIG. 2.

In the present embodiment, the depth (L2) of the second recessed section 260 is smaller than the depth (L1) of the first recessed section 160. That is, the second recessed section 260 is formed as a recessed section shallower than the first recessed section 160.

The base plate 200 is required to have a function of cooling the wafer W during processing via the dielectric substrate 100, and keeping an in-plane temperature distribution of the wafer W uniform. If the second recessed section 260 formed in the base plate 200 is formed to be deep, a cooling function of the base plate 200 in that part is lowered, and a temperature of the wafer W may locally increase immediately above that part. That is, a part of the wafer W immediately above the second recessed section 260 may become a so-called “hot spot”.

Thus, in the present embodiment, as described above, the second recessed section 260 is formed to be shallow so that L2 is smaller than L1. Since an increase in thermal resistance accompanying formation of the second recessed section 260 is suppressed to be smaller than that in the related art, a local temperature increase immediately above the conductive member 400 can be suppressed, and fluctuation in the in-plane temperature distribution of the wafer W during processing can be reduced.

In FIG. 2, “L3” is a dimension of the entire conductive member 400 along the direction perpendicular to the placement surface. Specifically, it is a dimension of the entire conductive member 400 along the direction perpendicular to the placement surface when the conductive member 400 is accommodated and compressed inside the first recessed section 160 and the second recessed section 260. L3 is equal to a distance from the bottom 162 of the first recessed section 160 to the bottom 262 of the second recessed section 260.

In the present embodiment, shapes of the conductive member 400, the first recessed section 160, and the second recessed section 260 are adjusted so that the dimension of the part of the conductive member 400 that is accommodated in the first recessed section 160 along the direction perpendicular to the placement surface (that is, L1) is ½ or more of the dimension of the entire conductive member 400 along the same direction (that is, L3).

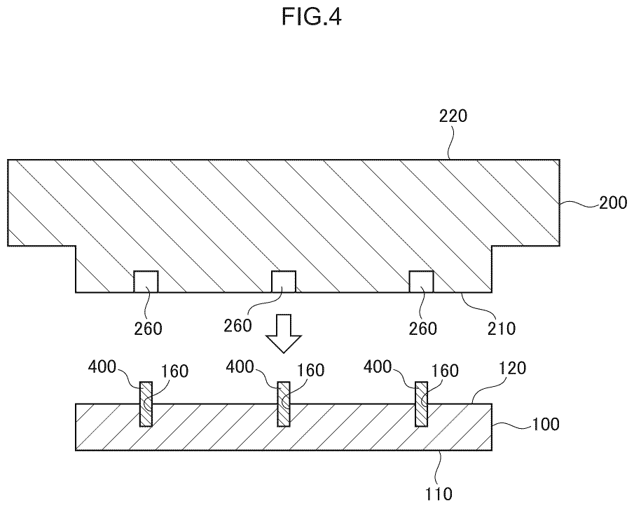

To explain advantages of adopting such a configuration, among methods of manufacturing the electrostatic chuck 10, a method of joining the dielectric substrate 100 and the base plate 200 will be described with reference to FIG. 4. In FIG. 4, configurations of the dielectric substrate 100, the base plate 200, and the conductive member 400 are simplified and schematically illustrated.

First, the dielectric substrate 100 is placed on a workbench which is not illustrated in the drawing in a state where the surface 120 faces upward. The first recessed section 160 is formed in the surface 120 in advance. An adhesive that becomes the joining layer 300 after curing is applied in advance to substantially the entire surface 120. The adhesive is not illustrated in FIG. 4. The adhesive may be applied in advance to the surface 220 of the base plate 200.

Subsequently, the conductive member 400 is inserted into each of the first recessed sections 160. As illustrated in FIG. 4, each of the conductive members 400 is in a state where a part thereof protrudes perpendicularly from the surface 120 of the dielectric substrate 100.

Thereafter, the base plate 200 is moved toward the surface 120 from the upper side in a state where the surface 210 faces downward. The second recessed section 260 is formed in the surface 210 in advance. The dielectric substrate 100 and the base plate 200 are aligned with each other so that each of the second recessed sections 260 is positioned immediately above the corresponding first recessed section 160. The base plate 200 is moved along an arrow in FIG. 4 to be joined to the dielectric substrate 100. When the movement is completed, each of the conductive members 400 is in a state of being accommodated inside the first recessed section 160 and the second recessed section 260. Thereafter, the electrostatic chuck 10 illustrated in FIG. 1 is completed by heating the whole and curing the above-described adhesive.

When the base plate 200 is moved along the arrow in FIG. 4, if the first recessed section 160 formed in the surface 120 is too shallow, the conductive member 400 inserted in the first recessed section 160 tends to fall down, and workability is significantly lowered. In a case where the diameter D1 of the inner circumferential surface 161 of the first recessed section 160 is too large, it is difficult to keep the conductive member 400 in a state of perpendicularly protruding from the surface 120, and a problem may occur in which a position of the conductive member 400 in that state cannot be accurately determined.

Thus, in the present embodiment, the diameter D1 of the inner circumferential surface 161 of the first recessed section 160 is made approximately equal to a diameter of the main body section 410 of the conductive member 400, and the depth (L1) of the first recessed section 160 is set to be ½ or more of the length (L3) of the entire conductive member 400. With such a configuration, it is possible to prevent a situation in which the conductive member 400 falls down when the dielectric substrate 100 and the base plate 200 are joined to each other.

If the diameter D2 of the inner circumferential surface 261 of the second recessed section 260 formed in the base plate 200 is smaller than the dimension in the present embodiment and, for example, is approximately equal to the diameter D1 of the inner circumferential surface 161 of the first recessed section 160, it is difficult to perform alignment when the base plate 200 is moved toward the dielectric substrate 100 on the lower side. That is, it is difficult to allow each of the conductive members 400 to intrude into the inside of the second recessed section 260.

Thus, in the present embodiment, shapes of the first recessed section 160 and the second recessed section 260 are devised so that the second recessed section 260 is larger than the first recessed section 160 in top view. Specifically, the diameter D2 of the inner circumferential surface 261 is made larger than the diameter D1 of the inner circumferential surface 161. Due to this, it is possible to allow each of the conductive members 400 to easily intrude into the inside of the second recessed section 260 while the base plate 200 is moved toward the lower side.

A second embodiment will be described. In the following, features different from those of the first embodiment will be mainly described, and description of features common to those of the first embodiment is omitted as appropriate.

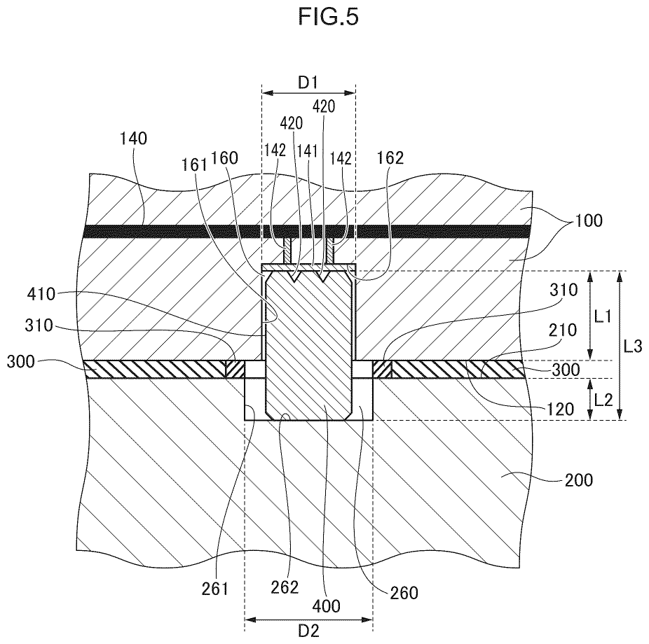

FIG. 5 illustrates a configuration of the electrostatic chuck 10 according to the present embodiment from the same viewpoint as in FIG. 2. As illustrated in FIG. 5, the first recessed section 160 of the present embodiment is not formed up to the depth position in which the RF electrode 140 is to be exposed. The bottom 162 of the first recessed section 160 is in a position on the surface 120 side relative to the RF electrode 140.

The bottom 162 of the first recessed section 160 is covered by a metallic plate 141. The metallic plate 141 is a plate-like member made of, for example, molybdenum and is closely attached to substantially the whole of the bottom 162. A distal end of the protrusion section 420 is pressed against the metallic plate 141 according to the present embodiment.

The metallic plate 141 and the RF electrode 140 are electrically connected to each other by a plurality of via sections 142 provided in the dielectric substrate 100. The via section 142 is obtained by filling the inner side of the hole formed so as to extend along the direction perpendicular to the surface 120 with a conductive member such as, for example, tungsten. One end of the via section 142 is connected to the metallic plate 141, and the other end is connected to the RF electrode 140.

In this manner, in the present embodiment, the conductive member 400 and the RF electrode 140 are not directly connected to each other and are indirectly connected to each other via the metallic plate 141 and the via sections 142. In such an aspect too, an effect similar to that described in the first embodiment can be attained.

In the present embodiment, “L1”, that is, the depth of the first recessed section 160 is equal to a distance from a surface on the base plate 200 side of the metallic plate 141 to the surface 120. In the present embodiment, similarly to the first embodiment, L2 is smaller than L1, and L1 is ½ or more of L3.

In the configuration of the present embodiment, an electric circuit in the via section 142 is relatively narrow, so that electrical resistance of the via section 142 may become large, and a large amount of Joule heat may be generated in the via section 142. To suppress a local temperature increase accompanied therewith, it is preferable to increase the depth (L1) of the first recessed section 160 and to shorten the via section 142 as much as possible. That is, in the configuration of the present embodiment, necessity of forming the first recessed section 160 and the like to satisfy L1>L2 is particularly high as compared with the first embodiment.

A third embodiment will be described. In the following, features different from those of the first embodiment will be mainly described, and description of features common to those of the first embodiment is omitted as appropriate.

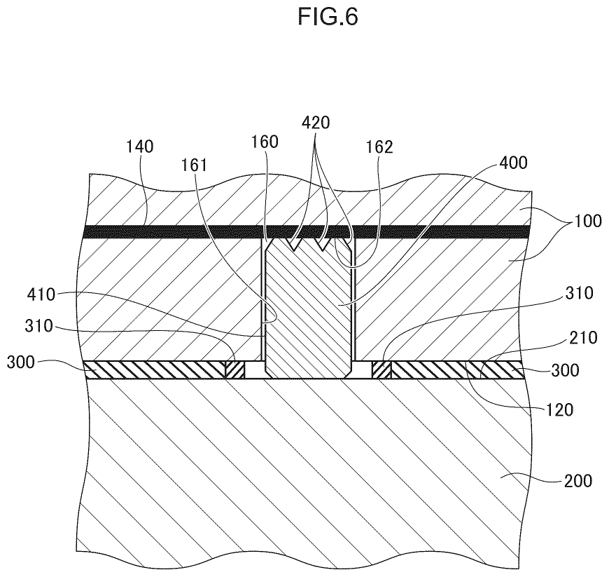

FIG. 6 illustrates a configuration of the electrostatic chuck 10 according to the present embodiment from the same viewpoint as in FIG. 2. In the present embodiment, the second recessed section 260 is not formed in the surface 210 of the base plate 200. An end part on the base plate 200 side of the conductive member 400 abuts against the surface 210 on the dielectric substrate 100 side of the base plate 200. It can also be said that such a configuration is a configuration in which the depth (L2) of the second recessed section 260 is set to 0. In such an aspect too, an effect similar to that described in the first embodiment can be attained.

As described in the first embodiment, an insulating film may be formed on the base plate 200 so as to cover the surface 210. In this case, at least in a part of the surface 210 against which the conductive member 400 abuts, it is only necessary to expose a metallic part of the base plate 200 without forming the insulating film.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
an internal electrode provided inside the dielectric substrate;
a base plate made of metal and joined to the dielectric substrate; and
a conductive member configured to electrically connect the internal electrode and the base plate to each other, wherein
a part of the conductive member is accommodated in a first recessed section formed in a surface on the base plate side of the dielectric substrate, and
an end part on the base plate side of the conductive member abuts against a surface on the dielectric substrate side of the base plate, or abuts against a bottom of a second recessed section that is formed in the surface on the dielectric substrate side of the base plate and is shallower than the first recessed section.

2. The electrostatic chuck according to claim 1, wherein a dimension of a part of the conductive member accommodated in the first recessed section along a direction perpendicular to the placement surface is ½ or more of a dimension of the entire conductive member along the same direction.

3. The electrostatic chuck according to claim 2, wherein
the second recessed section is formed in the base plate, and
the second recessed section is larger than the first recessed section when viewed from the direction perpendicular to the placement surface.
